(19) United States
(12) Patent Application Publication
(10) Pub. No.: US 2018/0301383 A1
(43) Pub. Date: Oct. 18, 2018

(54) SEMICONDUCTOR DEVICE

(71) Applicant: Samsung Electronics Co., Ltd., Suwon-si (KR)

(72) Inventor: Ju Youn KIM, Suwon-si (KR)

(21) Appl. No.: 15/844,534

(22) Filed: Dec. 16, 2017

(30) Foreign Application Priority Data
Apr. 13, 2017 (KR) 10-2017-0047712

(51) Int. Cl. H01L 21/8238; H01L 27/092; H01L 29/78

(52) U.S. Cl. CPC H01L 21/823842; H01L 29/7846; H01L 27/092

(57) ABSTRACT

A substrate has an NMOS region and a PMOS region. A first gate electrode structure is disposed on the NMOS region of the substrate. The first gate electrode structure includes a first barrier layer, a first gate electrode layer and a second barrier layer stacked as listed. A second gate electrode structure is disposed on the PMOS region. The second gate electrode structure includes a third barrier layer, a second gate electrode layer and a third gate electrode layer stacked as listed. The first gate electrode layer and the third gate electrode layer include substantially the same material. The second barrier layer and the second gate electrode layer include substantially the same material.

This application claims priority under 35 U.S.C. 119 to Korean Patent Application No. 10-2017-0047712 filed on Apr. 13, 2017 in the Korean Intellectual Property Office, the disclosure of which is incorporated by reference herein in its entirety.

### TECHNICAL FIELD

The present inventive concept relates to a semiconductor device.

### DISCUSSION OF RELATED ART

The semiconductor devices may include various functional blocks formed of transistors of which threshold voltages may be different. The functional blocks of the semiconductor devices may include a logic transistor, transistors for an SRAM (Static Random Access Memory) chip or transistors for a DRAM (Dynamic Random Access Memory) chip.

### SUMMARY

According to an exemplary embodiment of the present inventive concept, a semiconductor device is provided as follows. A substrate has an NMOS region and a PMOS region. A first gate electrode structure is disposed on the NMOS region of the substrate. The first gate electrode structure includes a first barrier layer, a first gate electrode layer and a second barrier layer stacked as listed. A second gate electrode structure is disposed on the PMOS region. The second gate electrode structure includes a third barrier layer, a second gate electrode layer and a third gate electrode layer stacked as listed. The first gate electrode layer and the third gate electrode layer include substantially the same material. The second barrier layer and the second gate electrode layer include substantially the same material.

According to an exemplary embodiment of the present inventive concept, a semiconductor device is provided as follows. A substrate has an NMOS region and a PMOS region. An interlayer insulating layer is disposed on the substrate with a first trench disposed in the NMOS region of the substrate and a second trench disposed in the PMOS region of the substrate. A first capping layer is disposed in an upper portion of the first trench. A first gate insulating layer is disposed in a lower portion of the first trench, extending along sidewalls and a bottom surface of the first trench. A first gate electrode structure is disposed in the lower portion of the first trench and on the first gate insulating layer. The first gate electrode structure includes a first barrier layer disposed on the first gate insulating layer, a first gate electrode layer disposed on the first barrier layer, and a second barrier layer disposed on the first gate electrode layer. A second capping layer is disposed in an upper portion of the second trench. A second gate insulating layer is disposed in a lower portion of the second trench, extending along sidewalls and a bottom surface of the second trench. A second gate electrode structure is disposed in the lower portion of the second trench and on the second gate insulating layer. The second gate electrode structure includes a third barrier layer disposed on the second gate insulating layer, a second gate electrode layer disposed on the third barrier layer, and a third gate electrode layer disposed on the second gate electrode layer. The second barrier layer, the first capping layer, the first gate insulating layer, the first barrier layer, and the first gate electrode layer fill the first trench. The third gate electrode layer, the second capping layer, the second gate insulating layer, the third barrier layer, and the second gate electrode layer fill the second trench. The first gate electrode layer and the third gate electrode layer include substantially the same material. The second barrier layer and the second gate electrode layer include substantially the same material. The second gate electrode layer and the third gate electrode layer include different materials.

According to an exemplary embodiment of the present inventive concept, a semiconductor device is provided as follows. A substrate has an NMOS region and a PMOS region. An interlayer insulating layer is disposed on the substrate with a first trench disposed in the NMOS region of the substrate and a second trench disposed in the PMOS region of the substrate. A first capping layer is disposed in an upper portion of the first trench. A first gate insulating layer is disposed in a lower portion of the first trench and extends along sidewalls and a bottom surface of the first trench. A first gate electrode structure is disposed in the lower portion of the first trench and on the first gate insulating layer. The first gate electrode structure includes a first barrier layer disposed on the first gate insulating layer, a first gate electrode layer disposed on the first barrier layer, and a second barrier layer disposed on the first gate electrode layer. A second capping layer is disposed in an upper portion of the second trench. A second gate insulating layer is disposed on a lower portion of the second trench and extends along sidewalls and a bottom surface of the second trench. A second gate electrode structure is disposed in the lower portion of the second trench and on the second gate insulating layer. The second gate electrode structure includes a third barrier layer disposed on the second gate insulating layer, and a fourth gate electrode layer disposed on the third barrier layer. The second barrier layer, the first gate insulating layer, the first barrier layer, and the first gate electrode layer fill the first trench. The fourth gate electrode layer, the second gate insulating layer, and the third barrier layer fill the second trench. The fourth gate electrode layer contains a nitride. The first gate electrode layer and the fourth gate electrode layer contain different materials.

### BRIEF DESCRIPTION OF THE DRAWINGS

These and other features of the present inventive concept will become more apparent by describing in detail exemplary embodiments thereof with reference to the accompanying drawings of which:

FIG. 1 is a layout diagram for explaining a semiconductor device according to some embodiments of the present inventive concept;

FIGS. 2A and 2B are cross-sectional views taken along line A-A′ and line B-B′ of FIG. 1;

FIG. 3 is an enlarged view of a region K of FIG. 2A; and

FIGS. 4 to 17 are views for explaining a semiconductor device according to some embodiments of the present inventive concept.

### DETAILED DESCRIPTION OF EXEMPLARY INVENTIVE CONCEPT

In the drawings of the semiconductor device according to some embodiments of the present inventive concept, a fin type transistor (FinFET) including a channel region of a fin-type pattern shape is exemplarily illustrated, but the present inventive concept is not limited thereto. The semiconductor device according to some embodiments of the present inventive concept, of course, may include a planar transistor, a tunneling transistor (FET), a transistor including a nanowire, a transistor including a nanosheet, or a three-dimensional (3D) transistor. Further, the semiconductor device according to some embodiments of the present inventive concept may include a bipolar junction transistor, a lateral double diffusion transistor (LDMOS), or the like.

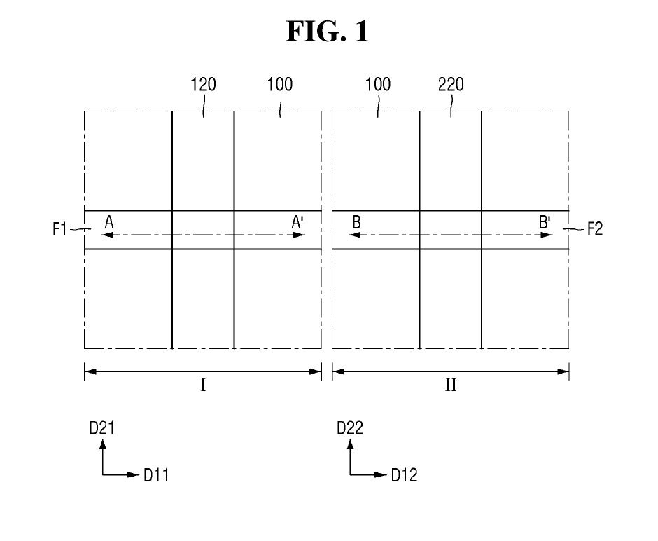

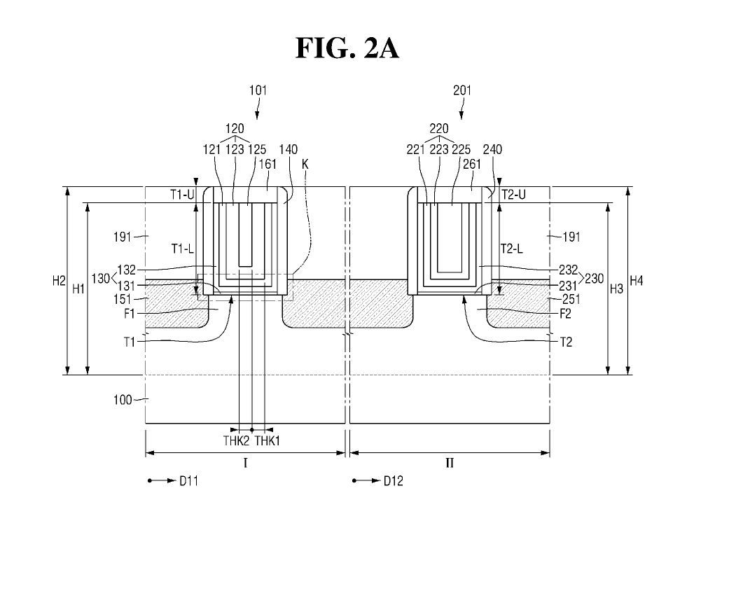

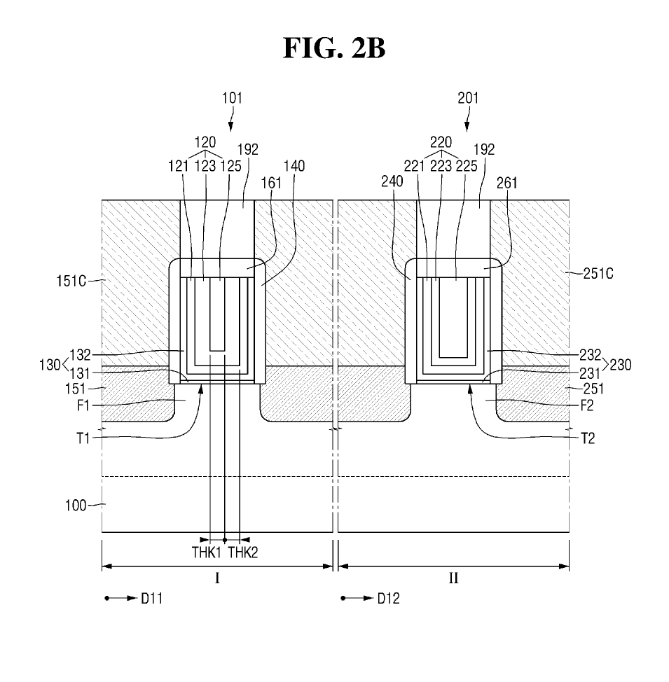

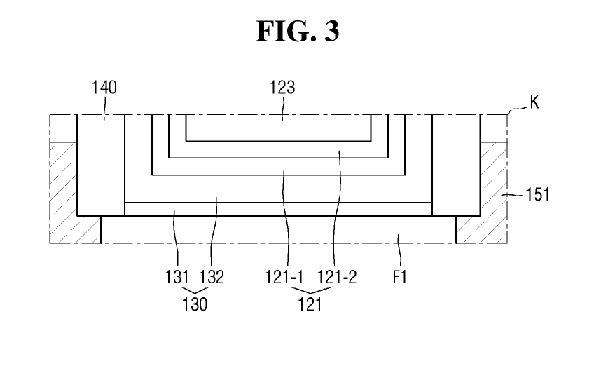

FIG. 1 is a layout diagram for explaining a semiconductor device according to some embodiments of the present inventive concept. FIGS. 2A and 2B are cross-sectional views taken along line A-A′ and line B-B′ of FIG. 1. FIG. 3 is an enlarged view of a region K of FIG. 2A. In FIG. 1, a first gate spacer 140, a second gate spacer 240, a first capping layer 161, a second capping layer 261, a first interlayer insulating layer 191, a second interlayer insulating layer 192, a first contact 151C and a second contact 251C are not illustrated to clarify illustration.

Referring to FIGS. 1 to 3, a semiconductor device according to some embodiments of the present inventive concept includes a first transistor 101 and a second transistor 201 formed on a substrate 100.

An NMOS region I and a PMOS region II are defined in the substrate 100. The NMOS region I and the PMOS region II are separated from each other, and the regions may be connected to each other. The NMOS region I and the PMOS region II may be included in the parts having the same function, that is, a logic region or an I/O region. Alternatively, the NMOS region I and the PMOS region II may be included in the parts having the different functions, that is, one of the logic region, the SRAM region, or the I/O region.

The substrate 100 may be bulk silicon or silicon-on-insulator (SOI). The substrate 100 may be a silicon substrate or may include, but is not limited to, other materials such as silicon germanium, a SGOI (silicon germanium on insulator), indium antimonide, lead tellurium compound, indium arsenide, phosphide indium, gallium arsenide, or gallium antimonide. In the following description, for convenience of explanation, the substrate 100 will be described as a substrate containing silicon.

A first fin-type pattern F1 and a first gate electrode structure 120 are disposed on the NMOS region I of the substrate 100. A second fin-type pattern F2 and a second gate electrode structure 220 are disposed on the PMOS region II of the substrate 100.

The first transistor 101 is formed in the NMOS region I, and the second transistor 201 is formed in the PMOS region. Therefore, the first transistor 101 is an n-type transistor, and the second transistor 201 is a p-type transistor.

The first transistor 101 includes a first gate insulating layer 130, a first gate electrode structure 120, a first gate spacer 140, a first capping layer 161, the first fin-type pattern F1 and a first source/drain 151.

The second transistor 201 may include a second gate insulating layer 230, a second gate electrode structure 220, a second gate spacer 240, a second capping layer 261, the second fin-type pattern F2 and a second source/drain 251.

The first fin-type pattern F1 and the second fin-type pattern F2 protrude from the substrate 100. The first fin-type pattern F1 extends along a first direction D11. The second fin-type pattern F2 may extend long along a second direction D12. Although the first direction D11 and the second direction D12 are illustrated as the same direction, the present inventive concept is not limited thereto. For example, the first direction D11 and the second direction D12 may be different directions.

The first fin-type pattern F1 and the second fin-type pattern F2 may be an epitaxial layer grown from the substrate 100. The present inventive concept is not limited thereto. For example, the substrate 100 may be patterned to form the first fin-type pattern F1 and the second fin-type pattern F2. Each of the first fin-type pattern F1 and the second fin-type pattern F2 may include, for example, silicon or germanium which is an element semiconductor material. Each of the first fin-type pattern F1 and the second fin-type pattern F2 may include a compound semiconductor, and may include, for example, a group IV-IV compound semiconductor or a group III-V compound semiconductor.

Specifically, when the IV-IV group compound semiconductor is taken as an example, the first fin-type pattern F1 and the second fin-type pattern F2 may be a binary compound or a ternary compound containing at least two or more of carbon (C), silicon (Si), germanium (Ge) and tin (Sn), or a compound doped with the group IV elements. When the group III-V compound semiconductor is taken as an example, each of the first fin-type pattern F1 and the second fin-type pattern F2 may be a binary compound, a ternary compound or a quaternary compound formed by bonding of at least one of aluminum (Al), gallium (Ga), and indium (In) as a group III element, and at least one of phosphorous (P), arsenic (As), and antimony (Sb) as a group V element.

For the convenience of descriptions, each of the first fin-type pattern F1 and the second fin-type pattern F2 will be assumed to be a silicon fin-type pattern.

The first gate electrode structure 120 is disposed on the first fin-type pattern F1, extending in a third direction D21 intersecting with the first fin-type pattern F1. The second gate electrode structure 220 is disposed on the second fin-type pattern F2, extending in a fourth direction D22 intersecting with the second fin-type pattern F2.

The first interlayer insulating layer 191 is disposed on the NMOS region I and the PMOS region II of the substrate 100. The first interlayer insulating layer 191 includes a first trench T1 and a second trench T2.

The first trench T1 is disposed on the NMOS region I of the substrate 100. The first trench T1 includes an upper portion T1-U of the first trench T1, and a lower portion T1-L of the first trench T1. The second trench T2 is disposed on the PMOS region II of the substrate 100. The second trench T2 includes an upper portion T2-U of the second trench T2 and a lower portion T2-L of the second trench T2.

The first interlayer insulating layer 191 may include, for example, silicon oxide, silicon nitride, silicon oxynitride, or a low-dielectric constant material. The low-dielectric constant material may include, but is not limited to, for example, FOX (Flowable Oxide), TOSZ (Torene SilaZene), USG (Undoped Silica Glass), BSG (Borosilica Glass), PSG (PhosphoSilica Glass), BPSG (Boro Phospho Silica Glass), PETEOS (Plasma Enhanced Tetra Ethyl Ortho Silicate), FSG (Fluoride Silicate Glass), CDO (Carbon Doped Silicon Oxide), Xerogel, Aerogel, Amorphous Fluorinated Carbon, OSG (Organo Silicate Glass), Parylene, BCB (bis-benzocyclobutenes), SiLK, polyimide, porous polymeric Material, or a combination thereof.

The first gate spacer 140 is disposed on the NMOS region I of the substrate 100. The first gate spacer 140 may define a first trench T1. For example, the first trench T1 may have the first gate spacer 140 as a sidewall of the first trench T1, and the upper surface of the first fin-type pattern F1 as the bottom surface of the first trench T1. The first gate spacer 140 may extend over an upper portion T1-U of the first trench T1 and a lower portion T1-L of the first trench T1.

The second gate spacer 240 is disposed on the PMOS region II of the substrate 100. The second gate spacer 240 may define a second trench T2. For example, the second trench T2 may have the second gate spacer 240 as a sidewall of the second trench T2 and the upper surface of the second fin-type pattern F2 as the bottom surface of the second trench T2. The second gate spacer 240 may extend over the upper portion T2-U of the second trench T2 and the lower portion T2-L of the second trench T2.

The first gate spacer 140 and the second gate spacer 240 may include, for example, silicon nitride (SiN), silicon oxynitride (SiON), silicon oxide (SiO₂), silicon oxycarbonitride (SiOCN), or a combination thereof.

Although each of the first gate spacer 140 and the second gate spacer 240 is illustrated as a single layer, this is for convenience of explanation. The present inventive concept is not limited thereto. For example, the first gate spacer 140 and the second gate spacer 240 include a plurality of layers. In this case, at least one of the plurality of layers included in the first gate spacer 140 and the second gate spacer 240 may contain a low-dielectric constant material such as silicon oxycarbonitride (SiOCN). In addition, at least one of the plurality of layers included in the first gate spacer 140 and the second gate spacer 240 may have an L-like shape. The first gate spacer 140 and the second gate spacer 240 may function as a guide for forming a self-aligned contact of the first gate electrode structure 120 and the second gate electrode structure 220. Therefore, the first gate spacer 140 and the second gate spacer 240 may include a material having etch selectivity with respect to the first interlayer insulating layer 191.

The first capping layer 161 is disposed in the upper portion T1-U of the first trench T1. The first gate insulating layer 130 and the first gate electrode structure 120 are disposed in the lower portion T1-L of the first trench T1. The first capping layer 161, the first gate insulating layer 130, and the first gate electrode structure 120 completely fill the first trench T1.

The first gate insulating layer 130 is disposed in the NMOS region I of the substrate 100. The first gate insulating layer 130 is disposed in the lower portion T1-L of the first trench T1, extended along the bottom surface of the first trench T1, and extended along a part of the sidewalls of the first trench T1. For example, the uppermost surface of the first gate insulating layer 130 may be lower than the upper surface of the first gate spacer 140 from the upper surface of the substrate 100. The uppermost surface of the first gate insulating layer 130, for example, is in contact with the first capping layer 161.

The first gate insulating layer 130 includes a first interfacial layer 131 and a first high-dielectric constant insulating layer 132. The first interfacial layer 131 is disposed on the upper surface of the first fin-type pattern F1. The first interfacial layer 131 is disposed on the bottom surface of the first trench T1. The first high-dielectric constant insulating layer 132 is disposed on the first interfacial layer 131. The first high-dielectric constant insulating layer 132 is disposed in the lower portion T1-L of the first trench T1, extending along a part of the bottom surface and the sidewall of the first trench T1.

The second capping layer 261 is disposed in the upper portion T2-U of the second trench T2. The second gate insulating layer 230 and the second gate electrode structure 220 are disposed in the lower portion T2-L of the second trench T2. The second capping layer 261, the second gate insulating layer 230, and the second gate electrode structure 220 completely fill the second trench T2.

The second gate insulating layer 230 is disposed on the PMOS region II of the substrate 100. The second gate insulating layer 230 is disposed in the lower portion T2-L of the second trench T2, extended along the bottom surface of the second trench T2, and extended along a part of the sidewalls of the second trench T2. For example, the uppermost surface of the second gate insulating layer 230 may be lower than the upper surface of the second gate spacer 240 from the upper surface of the substrate 100. The uppermost surface of the second gate insulating layer 230, for example, is in contact with the second capping layer 261.

The second gate insulating layer 230 includes a second interfacial layer 231 and a second high-dielectric constant insulating layer 232. The second interfacial layer 231 is disposed on the upper surface of the second fin-type pattern F2. The second interfacial layer 231 is disposed on the bottom surface of the second trench T2. The second high-dielectric constant insulating layer 232 is disposed on the second interfacial layer 231. The second high-dielectric constant insulating layer 232 is disposed in the lower portion T2-L of the second trench T2 and disposed along the bottom surface and the sidewall of the second trench T2.

Although the first interfacial layer 131 and the second interfacial layer 231 are illustrated as not being disposed on the sidewalls of the first trench T1 and the second trench T2, the inventive concept is not limited thereto. Depending on the method for forming the first interfacial layer 131 and the second interfacial layer 231, the first interfacial layer 131 and the second interfacial layer 231 may also be formed on the sidewalls of the first trench T1 and the second trench T2.

Each of the first interfacial layer 131 and the second interfacial layer 231 may include, for example, but is not limited to, silicon oxide. For example, depending on the type of the substrate 100 or the type of the first high-dielectric constant insulating layer 132 and the second high-dielectric constant insulating layer 232, the first interfacial layer 131 and the second interfacial layer 231 may contain other substances.

The first high-dielectric constant insulating layer 132 and the second high-dielectric constant insulating layer 232 may contain, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof.

The present inventive concept is not limited thereto. For example, the first high-dielectric constant insulating layer 132 and the second high-dielectric constant insulating layer 232 may contain, but is not limited to, one or more of a nitride (e.g., hafnium nitride) of the aforementioned metal material or an oxynitride (e.g., hafnium oxynitride).

The first gate insulating layer 130 and the second gate insulating layer 230 may be formed at the same level. Here, the term “the same level” means formation by the same manufacturing process.

The first gate electrode structure 120 is disposed in a lower portion T1-L of the first trench T1 and on the first gate insulating layer 130. The first gate electrode structure 120 fills the remaining part of the first trench T1 after the first capping layer 161 and the first gate insulating layer 130 are disposed in the first trench T1. In an exemplary embodiment, the first gate electrode structure 120, the first capping layer 161, and the first gate insulating layer 130 fill the first trench T1.

The first gate electrode structure 120 includes a first barrier layer 121, a first gate electrode layer 123, and a second barrier layer 125. In an exemplary embodiment, the first barrier layer 121, the first gate electrode layer 123, and the second barrier layer 125 are stacked in the listed order on the NMOS region I of the substrate 100.

The first barrier layer 121 is disposed on the first gate insulating layer 130. For example, the first barrier layer 121 is in contact with the first gate insulating layer 130. The first barrier layer 121 is disposed in the lower portion T1-L of the first trench T1, extending along the sidewall and the bottom surface of the first trench T1. The first barrier layer 121 extends along the sidewall of the lower portion T1-L of the first trench T1 and the bottom surface. The first barrier layer 121 is disposed along the profile of the first gate insulating layer 130. The uppermost surface of the first barrier layer 121, for example, is in contact with the first capping layer 161.

The first gate electrode layer 123 is disposed on the first barrier layer 121. The first gate electrode layer 123 is disposed on the lower portion T1-L of the first trench T1, extending along the sidewall and the bottom surface of the first trench T1. The first gate electrode layer 123 extends the sidewall and the bottom surface of the first trench T1. The first gate electrode layer 123 is disposed along the profile of the first barrier layer 121. The uppermost surface of the first gate electrode layer 123, for example, is in contact with the first capping layer 161.

The second barrier layer 125 is disposed on the first gate electrode layer 123. The second barrier layer 125 fills the lower portion T1-L of the first trench T1 with the first barrier layer 121 and the first gate electrode layer 123. In other words, the second barrier layer 125 may fill the remaining parts of the first trench T1 after the first capping layer 161, the first gate insulating layer 130, the first barrier layer 121, and the first gate electrode layer 123 are disposed in the first trench T1. In an exemplary embodiment, the second barrier layer 125, the first gate insulating layer 130, the first barrier layer 121, and the first gate electrode layer 123 fill the first trench T1.

The first capping layer 161 is disposed on the first gate electrode structure 120. For example, the first capping layer 161 is disposed on the second barrier layer 125. A first height H1 from the upper surface of the NMOS region I of the substrate 100 to the upper surface of the second barrier layer 125 is smaller than a second height H2 from the upper surface of the NMOS region I of the substrate 100 to the upper surface of the first interlayer insulating layer 191. The upper surface of the first interlayer insulating layer 191 is substantially coplanar with the upper surface of the first capping layer 161 at the second height H2.

The second gate electrode structure 220 is disposed in the lower portion T2-L of the second trench T2 and on the second gate insulating layer 230. The second gate electrode structure 220 fills the remaining part of the second trench T2, after the second capping layer 261 and the second gate insulating layer 230 are disposed in the second trench T2. In an exemplary embodiment, the second gate electrode structure 220, the second capping layer 261, and the second gate insulating layer 230 fill the second trench T2.

The second gate electrode structure 220 includes a third barrier layer 221, a second gate electrode layer 223, and a third gate electrode layer 225. In an exemplary embodiment, the third barrier layer 221, the second gate electrode layer 223, and the third gate electrode layer 225 are stacked in the listed order on the PMOS region II of the substrate 100. In an exemplary embodiment, the second gate electrode layer 223 and the third gate electrode layer 225 include different materials.

The third barrier layer 221 is disposed on the second gate insulating layer 230. For example, the third barrier layer 221 is in contact with the second gate insulating layer 230. The third barrier layer 221 is disposed in the lower portion T2-L of the second trench T2, extending along the sidewall and the bottom surface of the second trench T2. The third barrier layer 221 extends along the sidewall of the lower portion T2-L of the second trench T2 and the bottom surface of the second trench T2. The third barrier layer 221 is disposed along the profile of the second gate insulating layer 230. The uppermost surface of the third barrier layer 221, for example, is in contact with the second capping layer 261.

The second gate electrode layer 223 may be disposed on the third barrier layer 221. The second gate electrode layer 223 is disposed in the lower portion T2-L of the second trench T2, extending along the sidewall and the bottom surface of the second trench T2. The second gate electrode layer 223 extends along the sidewall of the lower portion T2-L of the second trench T2 and the bottom surface of the second trench T2. The second gate electrode layer 223 is disposed along the profile of the third barrier layer 221. The uppermost surface of the second gate electrode layer 223, for example, is in contact with the second capping layer 261.

The third gate electrode layer 225 is disposed on the second gate electrode layer 223. The third gate electrode layer 225 fills the lower portion T2-L of the second trench T2 with the third barrier layer 221 and the second gate electrode layer 223. In other words, the third gate electrode layer 225 may fill the remaining part of the second trench T2, after the second capping layer 261, the second gate insulating layer 230, the third barrier layer 221, and the second gate electrode layer 223 are disposed in the second trench T2. In an exemplary embodiment, the third gate electrode layer 225, the second capping layer 261, the second gate insulating layer 230, the third barrier layer 221, and the second gate electrode layer 223 fill the second trench T2.

The second capping layer 261 is disposed on the second gate electrode structure 220. For example, the second capping layer 261 is disposed on the third gate electrode layer 225. A third height H3 from the upper surface of the PMOS region II of the substrate 100 to the upper surface of the third gate electrode layer 225 is smaller than a fourth height H4 from the upper surface of the PMOS region II of the substrate 100 to the upper surface of the first interlayer insulating layer 191. The upper surface of the first interlayer insulating layer 191 is substantially coplanar with the upper surface of the second capping layer 261 at the fourth height H4.

A first thickness THK1 of the first gate electrode layer 123 may be substantially the same as a second thickness THK2 of the second barrier layer 125 or may be smaller than the second thickness THK2 of the second barrier layer 125. Here, the first thickness THK1 and the second thickness THK2 are measured along the first direction D11.

The first source/drain 151 and the second source/drain 251 are disposed adjacent to the first gate electrode structure 120 and the second gate electrode structure 220, respectively. Each of the first source/drain 151 and the second source/drain 251 may include, but is not limited to, an epitaxial layer formed in the substrate 100. For example, each of the first source/drain 151 and the second source/drain 251 may be an impurity region formed by implanting impurities into the substrate 100. Further, each of the first source/drain 151 and the second source/drain 251 may be a raised source/drain including an upper surface protruding upward from the upper surface of the substrate 100.

In FIG. 2B, the first source/drain 151 is connected to the first contact 151C, and the second source/drain 251 is connected to the second contact 251C. The second interlayer insulating layer 192 may be disposed on the first capping layer 161 and the second capping layer 261. The second interlayer insulating layer 192 may include, but is not limited to, substantially the same material as the first interlayer insulating layer 191. The “substantially the same material” may include any difference in amounts of elements in due to process variation or spatial variation.

The first contact 151C penetrates the first interlayer insulating layer 191 and the second interlayer insulating layer 192 to contact the first source/drain 151. The second contact 251C penetrates the first interlayer insulating layer 191 and the second interlayer insulating layer 192 to contact the second source/drain 251.

The first contact 151C and the second contact 251C may include, for example, W, Al, or Cu.

In the following drawings, the first contact 151C and the second contact 251C are omitted, but the present inventive concept is not limited thereto. For example, in all the embodiments of the present inventive concept, it is a matter of course that the second interlayer insulating layer 192 may be further disposed on the first interlayer insulating layer 191, and the first contact 151C, and the second contact 251C extending to the first source/drain 151 and the second source/drain 251 may be further disposed to pass through the second interlayer insulating layer 192.

Referring again to FIGS. 1 to 3, the first barrier layer 121 and the third barrier layer 221 may include a metal nitride. For example, the first barrier layer 121 and the third barrier layer 221 may include titanium nitride (TiN) or tantalum nitride (TaN).

The first barrier layer 121 and the third barrier layer 221 may be formed at the same level during the manufacturing process of the semiconductor device according to some embodiments of the present inventive concept. For example, during the manufacturing process of the semiconductor device according to some embodiments of the present inventive concept, the first barrier layer 121 and the third barrier layer 221 may be formed by performing a nitriding process of a preliminary first barrier layer and a preliminary third barrier layer after formation thereof. The nitriding process may be performed using a gas containing nitrogen at a predetermined percentage of the process gas. The first barrier layer 121 and the third barrier layer 221 may contain a greater amount of nitrogen than the preliminary first barrier layer and the preliminary third barrier layer.

In some embodiments, the first barrier layer 121 and the third barrier layer 221 may be a single layer. In this case, the first barrier layer 121 and the third barrier layer 221 may include, for example, titanium nitride (TiN). The first barrier layer 121 is in contact with the first gate insulating layer 130, and the third barrier layer 221 is in contact with the second gate insulating layer 230.

However, the present inventive concept is not limited thereto. The first barrier layer 121 and the third barrier layer 221 may include two or more layers. For example, as illustrated in FIG. 3, the first barrier layer 121 includes two layers. The first barrier layer 121 includes a first layer 121-1 disposed on the first gate insulating layer 130 and in contact with the first gate insulating layer 130, and a second layer 121-2 interposed between the first layer 121-1 and the first gate electrode layer 123. In this case, the first layer 121-1 may include, for example, titanium nitride (TiN), and the second layer 121-2 may include, for example, tantalum nitride (TaN).

Similarly to the configuration of the first barrier layer 121, the third barrier layer 221 may include a third layer disposed on the second gate insulating layer 230 and in contact with the second gate insulating layer 230, and a fourth layer interposed between the third layer and the second gate electrode layer 223. In this case, the third layer, for example, may include titanium nitride (TiN), and the fourth layer, for example, may include tantalum nitride (TaN).

If the first barrier layer 121 and the third barrier layer 221 are multi-layered to have two or more layers, during the manufacturing process of the semiconductor device according to some embodiments of the present inventive concept, the second layer 121-2 and the fourth layer may be formed at the same level. After forming a preliminary second layer and a preliminary fourth layer, the nitriding process may be performed on the preliminary second layer and the preliminary fourth layer to form the second layer 121-2 and the fourth layer. The second layer 121-2 and the fourth layer may contain more amount of nitrogen than the preliminary second layer and the preliminary fourth layer.

The first capping layer 161 and the second capping layer 261 may include, for example, a nitride or an oxide. In some embodiments, the first capping layer 161 and the second capping layer 261 may contain SiN, SiON, or SiCON. The first capping layer 161 and the second capping layer 261 may protect each of the first gate electrode structure 120 and the second gate electrode structure 220 to prevent a change in performance. As a result, the first capping layer 161 and the second capping layer 261 may keep the threshold voltages of the first gate electrode structure 120 and the second gate electrode structure 220 constant.

The first gate electrode layer 123 and the third gate electrode layer 225 may contain substantially the same material. For example, the first gate electrode layer 123 and the third gate electrode layer 225 may contain Ti, TiAl, TiAlN, TiAlC, or TiAlCN. The first gate electrode layer 123 and the third gate electrode layer 225 may contain an n-type work function control material. In some embodiments, the first gate electrode layer 123 and the third gate electrode layer 225 may contain titanium aluminum carbide (TiAlC).

For example, the first gate electrode layer 123 and the third gate electrode layer 225 may be formed at the same level.

The second barrier layer 125 and the second gate electrode layer 223 may contain substantially the same material. For example, the second barrier layer 125 and the second gate electrode layer 223 may include a metal nitride (for example, titanium nitride (TiN)).

On the other hand, the second barrier layer 125 and the second gate electrode layer 223 need not be formed at the same level. For example, the nitrogen content of the second barrier layer 125 may be different from the nitrogen content of the second gate electrode layer 223.

For example, during the manufacturing process of the semiconductor device according to some embodiments of the present inventive concept, the second gate electrode layer 223 may be formed by performing a nitriding process of the preliminary second gate electrode layer after the preliminary second gate electrode layer is formed. The second gate electrode layer 223 may contain a greater amount of nitrogen than the preliminary second gate electrode layer. On the other hand, for example, the nitriding process need not be performed on the second barrier layer 125.

The first gate electrode layer 123, the second gate electrode layer 223, and the third gate electrode layer 225 may serve to adjust the work function of each transistor to adjust the operation characteristics. As described above, if the first transistor 101 operates as an n-type transistor, the first gate electrode layer 123 contains an n-type work function control material (e.g., TiAlC). On the other hand, the second transistor 201 includes the second gate electrode layer 223 and the third gate electrode layer 225, but the second gate electrode layer 223 may adjust the work function of the second transistor 201. As described above, if the second transistor 201 operates as a p-type transistor, the second gate electrode layer 223 contains a p-type work function control substance (e.g., TiN).

In FIG. 2A, in the first transistor 101, a layer including titanium nitride (TiN) is not disposed between the first barrier layer 121 and the first gate electrode layer 123. Meanwhile, since the second transistor 201 includes the second gate electrode layer 223 including TiN, the types according to the threshold voltages of the first transistor 101 and the second transistor 201 may be different from each other.

For example, the first transistor 101 may be an n-type low-voltage transistor. The second transistor 201 may be a p-type regular voltage transistor.

The threshold voltages of the first transistor 101 and the second transistor 201 may be adjusted, using the nitrogen content contained in the first barrier layer 121 and the third barrier layer 221, the thicknesses of the first gate electrode layer 123, the second gate electrode layer 223 and the third gate electrode layer 225, or the nitrogen contents contained in the second gate electrode layer 223.

For example, when the nitrogen content of the first barrier layer 121 is larger than the nitrogen content of the preliminary first barrier layer, the threshold voltage of the first transistor 101 may become lower as compared with the case where the nitrogen content of the preliminary first barrier layer is not larger than the nitrogen content of the first barrier layer 121.

Meanwhile, when the nitrogen content of the preliminary third barrier layer is made to larger than the nitrogen content of the third barrier layer 221, the threshold voltage of the second transistor 201 may become lower than the case where the nitrogen content of the preliminary third barrier layer is not larger than the nitrogen content of the third barrier layer 221.

Further, when the nitrogen content of the preliminary second gate electrode layer is made to be larger than the nitrogen content of the second gate electrode layer 223, the threshold voltage of the second transistor 201 may become lower than the case where the nitrogen content of the preliminary second gate electrode layer is not larger than the nitrogen content of the second gate electrode layer 223.

It is possible to increase the nitrogen content of the third barrier layer 221 and the nitrogen content of the second gate electrode layer 223 through the nitriding process.

The adjustment of the threshold voltage of a transistor using the combination of the thicknesses of the first gate electrode layer 123, the second gate electrode layer 223, and the third gate electrode layer 225 will be described later.

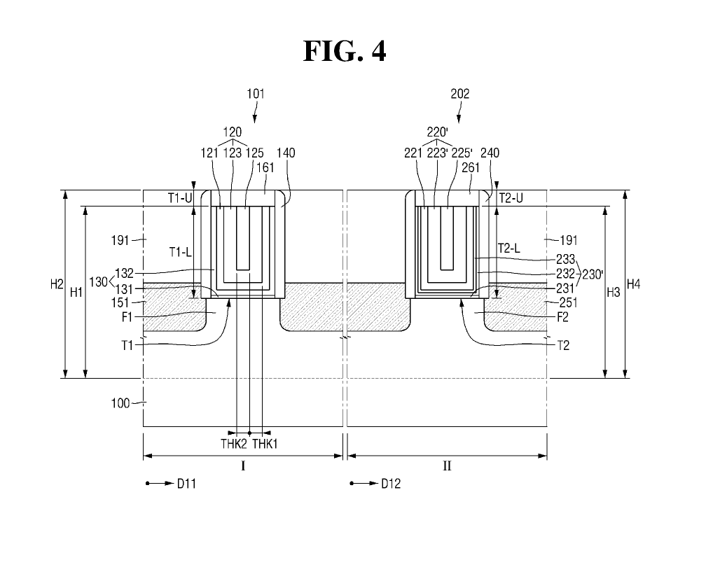

FIG. 4 is a view for explaining a semiconductor device according to some embodiments of the present inventive concept. FIG. 4 is a cross-sectional view taken along line A-A′ and line B-B′ of FIG. 1. For the sake of convenience of explanation, differences from those described above will be described.

Referring to FIGS. 1 to 4, a third transistor 202 is formed in the PMOS region II.

The first transistor 101 formed in the NMOS region I may be the same as the first transistor 101 of FIG. 2A.

The third transistor 202 includes a second gate insulating layer 230′, a second gate electrode structure 220′, a second gate spacer 240, a second capping layer 261, a second fin-type pattern F2, and a second source/drain 251.

The difference between the second gate insulating layer 230′ and the second gate insulating layer 230 of FIG. 2A is that the second gate insulating layer 230′ further includes a first oxide layer 233.

The first oxide layer 233 is disposed on the second high-dielectric constant insulating layer 232 and is interposed between the second high-dielectric constant insulating layer 232 and the third barrier layer 221. The first oxide layer 233 is disposed in the lower portion T2-L of the second trench, extending along the bottom surface and sidewalls of the second trench T2. The first oxide layer 233 extends along a part of the bottom surface and the sidewall of the second trench T2. For example, the first oxide layer 233 is disposed along the profile of the second high-dielectric constant insulating layer 232.

The first oxide layer 233 may contain an element of lanthanide series. For example, the first oxide layer 233 may contain LaO.

The second gate electrode structure 220′ includes a third barrier layer 221, a second gate electrode layer 223′, and a third gate electrode layer 225′.

The difference between the second gate electrode layer 223′ and the second gate electrode layer 223 of FIG. 2A is a difference in thickness. The thickness of the second gate electrode layer 223′ may be greater than the thickness of the second gate electrode layer 223 of FIG. 2A.

The difference between the third gate electrode layer 225′ and the third gate electrode layer 225 of FIG. 2A is a difference in thickness. The thickness of the third gate electrode layer 225′ may be smaller than the thickness of the third gate electrode layer 225 of FIG. 2A.

As the thickness of the second gate electrode layer 223′ including the p-type work function control material (e.g., TiN) is thicker than the thickness of the second gate electrode layer 223 of FIG. 2A, and the thickness of the third gate electrode layer 225′ including the n-type work function control material (e.g., TiAlC) is thinner than the thickness of the third gate electrode layer 225 of FIG. 2A, the threshold voltage of the third transistor 202 may be lower than the threshold voltage of the second transistor 201. The third transistor 202 may be, for example, a p-type low-voltage transistor.

In an exemplary embodiment, by adjusting the thicknesses of the second gate electrode layer 223 and the third gate electrode layer 225, the threshold voltage of the transistor in the PMOS region II may be adjusted.

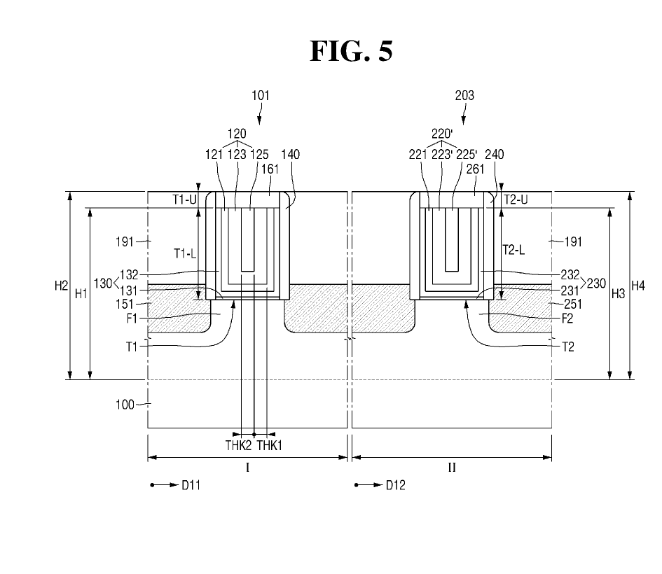

FIG. 5 is a diagram illustrating a semiconductor device according to some embodiments of the present inventive concept. FIG. 5 is a cross-sectional view taken along line A-A′ and line B-B′ of FIG. 1. For the sake of convenience of explanation, differences from those described above will be described.

Referring to FIGS. 1 to 5, a fourth transistor 203 is formed in the PMOS region II.

The first transistor 101 formed in the NMOS region I may be the same as the first transistor 101 of FIG. 2A.

The fourth transistor 203 includes a second gate insulating layer 230, a second gate electrode structure 220′, a second gate spacer 240, a second capping layer 261, a second fin-type pattern F2 and a second source/drain 251.

Compared with the third transistor 202 of FIG. 4, the fourth transistor 203 need not include the first oxide layer 233. Therefore, the threshold voltage of the fourth transistor 203 may be lower than the threshold voltage of the third transistor 202.

Further, as compared with the second transistor 201 of FIG. 2A, the thickness of the second gate electrode layer 223′ may be thicker than the thickness of the second gate electrode layer 223. Therefore, the threshold voltage of the fourth transistor 203 may be lower than the threshold voltage of the second transistor 201.

For example, the fourth transistor 203 may be a p-type super-low voltage transistor.

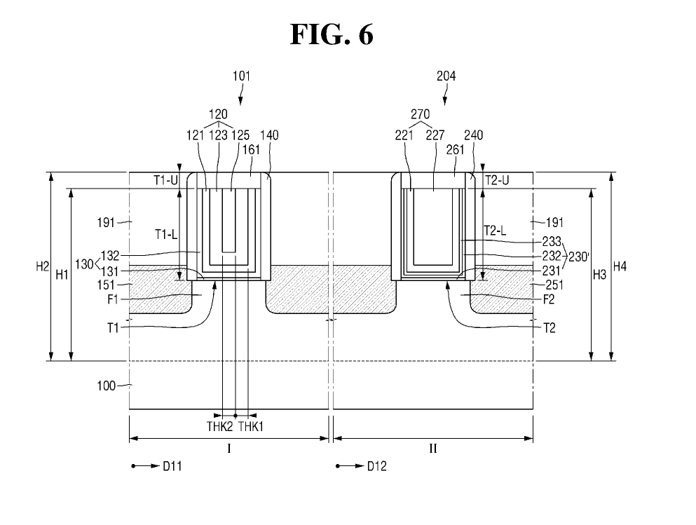

FIG. 6 is a diagram illustrating a semiconductor device according to some embodiments of the present inventive concept. FIG. 6 is a cross-sectional view taken along line A-A′ and a line B-B′ of FIG. 1. For the sake of convenience of explanation, differences from those described above will be described.

Referring to FIGS. 1 to 6, a fifth transistor 204 may be formed in the PMOS region II.

The first transistor 101 formed in the NMOS region I may be the same as the first transistor 101 of FIG. 2A.

The fifth transistor 204 includes a second gate insulating layer 230′, a third gate electrode structure 270, a second gate spacer 240, a second capping layer 261, a second fin-type pattern F2, and a second source/drain 251.

The third gate electrode structure 270 includes a third barrier layer 221 and a fourth gate electrode layer 227.

The fourth gate electrode layer 227 is disposed in the lower portion T2-L of the second trench T2 and is disposed on the third barrier layer 221. The fourth gate electrode layer 227 fills the remaining part of the second trench T2, after the second capping layer 261, the second gate insulating layer 230, and the third barrier layer 221 are disposed in the second trench T2. The second capping layer 261 is disposed on the third gate electrode structure 270. The second capping layer 261 is disposed on the third gate electrode structure 270. In an exemplary embodiment, the fourth gate electrode layer 227, the second capping layer 261, the second gate insulating layer 230, and the third barrier layer 221 fill the trench T2.

The fourth gate electrode layer 227 may include, for example, a metal nitride. For example, the fourth gate electrode layer 227 may include titanium nitride (TiN).

During the manufacturing process of the semiconductor device according to some embodiments of the present inventive concept, the fourth gate electrode layer 227 may be formed, by performing a nitriding process of a preliminary fourth gate electrode layer, after the preliminary fourth gate electrode layer is formed. The fourth gate electrode layer 227 may contain a greater amount of nitrogen than the preliminary fourth gate electrode layer.

For example, the fifth transistor 204 may be a p-type low-voltage transistor. Compared to the third transistor 202 which is a p-type low voltage transistor, the third gate electrode structure 270 of the fifth transistor 204 may substantially hardly contain the n-type work function control material (e.g., TiAlC). Therefore, the threshold voltage of the fifth transistor 204 may be lower than that of the third transistor 202 of the same type.

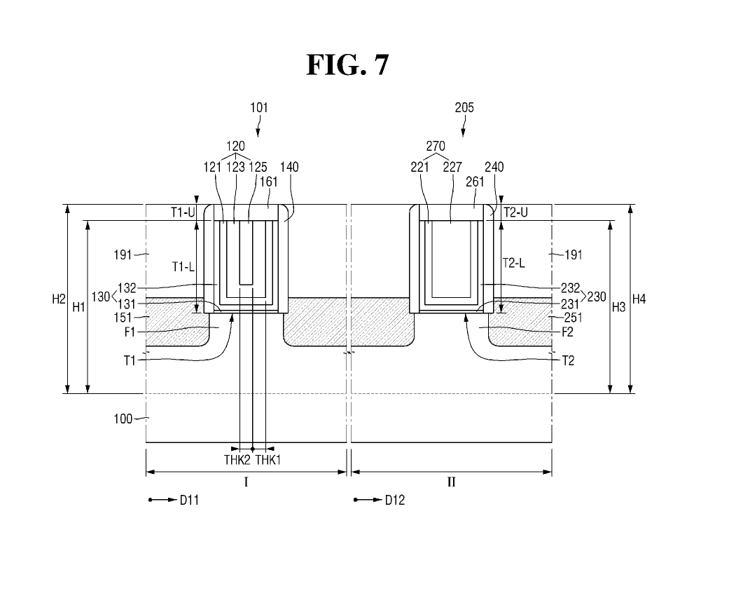

FIG. 7 is a view for explaining a semiconductor device according to some embodiments of the present inventive concept. FIG. 7 is a cross-sectional view taken along line A-A′ and a line B-B′ of FIG. 1. For the sake of convenience of explanation, differences from those described above will be described.

Referring to FIGS. 1 to 7, a sixth transistor 205 is formed in the PMOS region II.

The first transistor 101 formed in the NMOS region I may be the same as the first transistor 101 of FIG. 2A.

The sixth transistor 205 includes a second gate insulating layer 230, a third gate electrode structure 270, a second gate spacer 240, a second capping layer 261, a second fin-type pattern F2, and second source/drain 251.

As compared with the fifth transistor 204, the sixth transistor 205 need not include the first oxide layer 233. Therefore, the threshold voltage of the sixth transistor 205 may be lower than the threshold voltage of the fifth transistor 204.

For example, the sixth transistor 205 may be a p-type super-low voltage transistor. As compared with the fourth transistor 203 which is a p-type super-low voltage transistor, the third gate electrode structure 270 of the sixth transistor 205 may substantially hardly contain the n-type work function control material (e.g., TiAlC). Therefore, the threshold voltage of the sixth transistor 205 may be lower than that of the fourth transistor 203 of the same type.

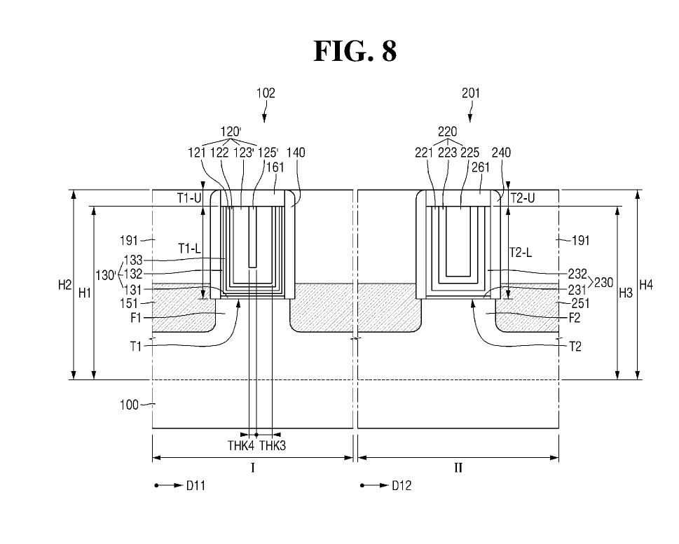

FIG. 8 is a diagram illustrating a semiconductor device according to some embodiments of the present inventive concept. FIG. 8 is a cross-sectional view taken along line A-A′ and line B-B′ of FIG. 1. For the sake of convenience of explanation, differences from those described above will be described.

Referring to FIGS. 1, 2A and 8, a seventh transistor 102 is formed in the NMOS region I.

The second transistor 201 formed in the PMOS region II may be the same as the second transistor 201 of FIG. 2A.

The seventh transistor 102 may include a first gate insulating layer 130′, a first gate electrode structure 120′, a first gate spacer 140, a first capping layer 161, a first fin-type pattern F1, and a first source/drain 151.

The difference between the first gate insulating layer 130′ and the first gate insulating layer 130 of FIG. 2a is that the first gate insulating layer 130′ further includes the second oxide layer 133.

The second oxide layer 133 is disposed on the first high-dielectric constant insulating layer 132 and is interposed between the first high-dielectric constant insulating layer 132 and the first barrier layer 121. The second oxide layer 133 is disposed in the lower portion T1-L of the first trench T1, extending along the bottom surface and the sidewall of the first trench T1. The second oxide layer 133 extends along a part of the bottom surface and the sidewall of the first trench T1. For example, the second oxide layer 133 is disposed along the profile of the first high-dielectric constant insulating layer 132.

The second oxide layer 133 may contain elements of lanthanide series. For example, the second oxide layer 133 may contain LaO.

The first gate electrode structure 120′ includes a first barrier layer 121, a fifth gate electrode layer 122, a first gate electrode layer 123′, and a second barrier layer 125′.

The difference between the first gate electrode layer 123′ and the first gate electrode layer 123 of FIG. 2A is a difference in thickness. The thickness THK3 of the first gate electrode layer 123′ may be greater than the thickness THK1 of the first gate electrode layer 123 of FIG. 2A.

The difference between the second barrier layer 125′ and the second barrier layer 125 of FIG. 2A is a different in thickness. The thickness THK4 of the second barrier layer 125′ may be smaller than the thickness THK2 of the second barrier layer 125 of FIG. 2A.

The thickness THK3 of the first gate electrode layer 123′ may be greater than the thickness THK4 of the second barrier layer 125′.

The fifth gate electrode layer 122 is interposed between the first barrier layer 121 and the first gate electrode layer 123′. For example, the fifth gate electrode layer 122 is disposed along the profile of the first barrier layer 121.

The thickness of the fifth gate electrode layer 122 may be smaller than the thickness of the second gate electrode layer 223.

The fifth gate electrode layer 122 and the second gate electrode layer 223 may contain substantially the same material. For example, the fifth gate electrode layer 122 and the second gate electrode layer 223 may include, for example, a metal nitride. The fifth gate electrode layer 122 and the second gate electrode layer 223 may contain, for example, titanium nitride (TiN).

In an exemplary embodiment, the fifth gate electrode layer 122 and the second gate electrode layer 223 may be formed at the same level. Each of the fifth gate electrode layer 122 and the second gate electrode layer 223 may be formed, by performing a nitriding process on a preliminary fifth gate electrode layer and a preliminary second gate electrode layer, after the preliminary fifth gate electrode layer and the preliminary second gate electrode layer are formed. In this case, each of the fifth gate electrode layer 122 and the second gate electrode layer 223 may have a larger amount of nitrogen than each of the preliminary fifth gate electrode layer and the preliminary second gate electrode layer.

In an exemplary embodiment, in the case of an n-type transistor, by adjusting the thicknesses of the first gate electrode layer 123 and the first gate electrode layer 123′, the threshold voltage may be adjusted. For example, the threshold voltage of the first transistor 101 may be lower than the threshold voltage of the seventh transistor 102. For example, the seventh transistor 102 may be an n-type regular voltage transistor.

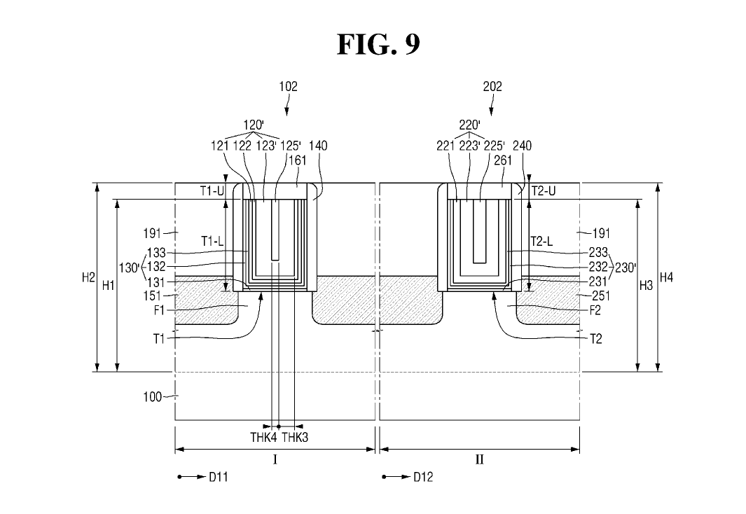

FIG. 9 is a view for explaining a semiconductor device according to some embodiments of the present inventive concept. FIG. 9 is a cross-sectional view taken along line A-A′ and line B-B′ of FIG. 1. For the sake of convenience of explanation, differences from those described above will be described.

Referring to FIGS. 1, 4, 8, and 9, a third transistor 202 is formed in the PMOS region II. The third transistor 202 may be the same as the third transistor 202 of FIG. 4. The seventh transistor 102 formed in the NMOS region I may be the same as the seventh transistor 102 of FIG. 8.

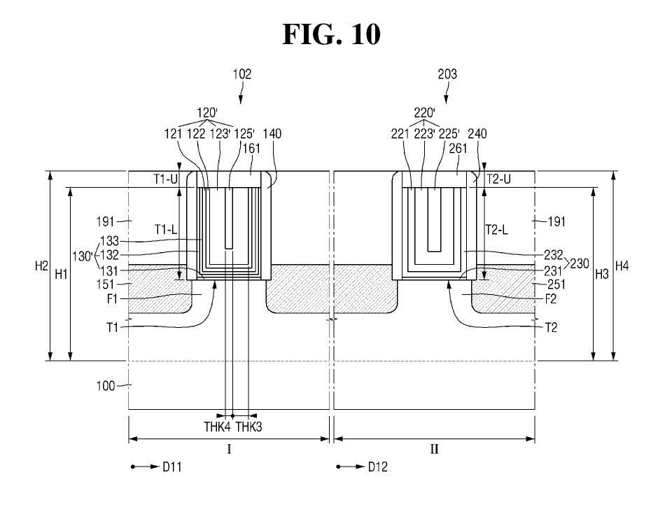

FIG. 10 is a view for explaining a semiconductor device according to some embodiments of the present inventive concept. FIG. 10 is a cross-sectional view taken along line A-A′ and line B-B′ of FIG. 1. For the sake of convenience of explanation, differences from those described above will be described.

Referring to FIGS. 1, 5, 8, and 10, a fourth transistor 203 may be formed in the PMOS region II. The fourth transistor 203 may be the same as the fourth transistor 203 of FIG. 5. The seventh transistor 102 formed in the NMOS region I may be the same as the seventh transistor 102 of FIG. 8.

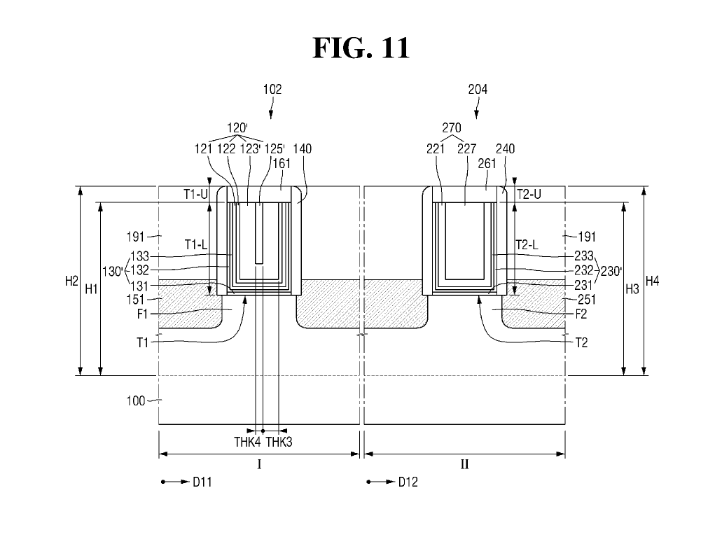

FIG. 11 is a diagram for explaining a semiconductor device according to some embodiments of the present inventive concept. FIG. 11 is a cross-sectional view taken along line A-A′ and line B-B′ of FIG. 1. For the sake of convenience of explanation, differences from those described above will be described.

Referring to FIGS. 1, 6, 8, and 11, a fifth transistor 204 may be formed in the PMOS region II. The fifth transistor 204 may be the same as the fifth transistor 204 of FIG. 6. The seventh transistor 102 formed in the NMOS region I may be the same as the seventh transistor 102 of FIG. 8.

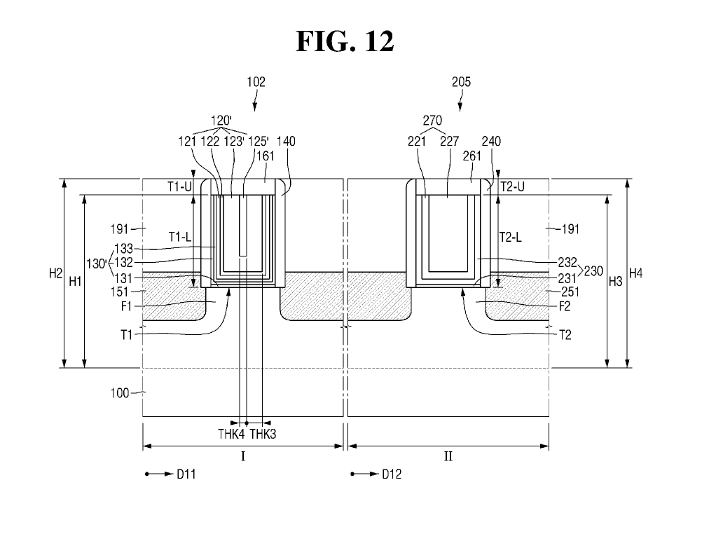

FIG. 12 is a diagram for explaining a semiconductor device according to some embodiments of the present inventive concept. FIG. 12 is a cross-sectional view taken along line A-A′ and line B-B′ of FIG. 1. For the sake of convenience of explanation, differences from those described above will be described.

Referring to FIGS. 1, 7, 8, and 12, a sixth transistor 205 is formed in the PMOS region II. The sixth transistor 205 may be the same as the sixth transistor 205 of FIG. 7. The seventh transistor 102 formed in the NMOS region may be the same as the seventh transistor 102 of FIG. 8.

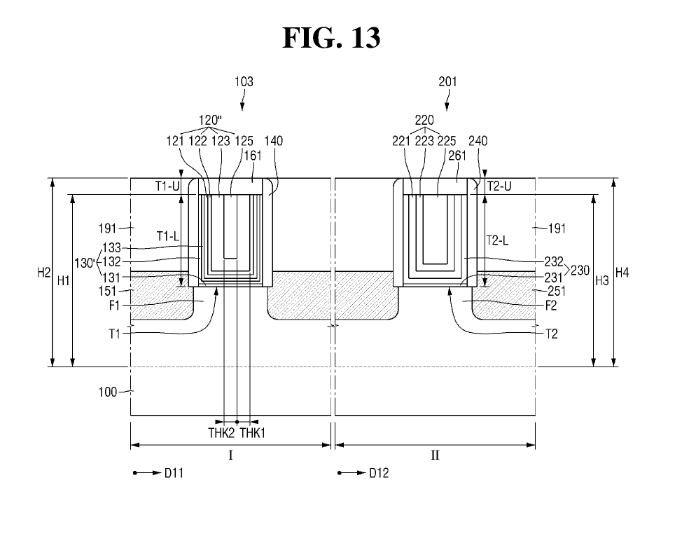

FIG. 13 is a view for explaining a semiconductor device according to some embodiments of the present inventive concept. FIG. 13 is a cross-sectional view taken along line A-A′ and line B-B′ of FIG. 1. For the sake of convenience of explanation, differences from those described above will be described.

Referring to FIGS. 1, 2A, 8, and 13, an eighth transistor 103 is formed in the NMOS region I.

The second transistor 201 formed in the PMOS region II may be the same as the second transistor 201 of FIG. 2A.

The eighth transistor 103 includes a first gate insulating layer 130′, a first gate electrode structure 120″, a first gate spacer 140, a first capping layer 161, a first fin-type pattern F1, and a first source/drain 151.

The first gate electrode structure 120″ includes a first barrier layer 121, a fifth gate electrode layer 122, a first gate electrode layer 123, and a second barrier layer 125.

The difference between the first transistor 101 of FIG. 2A and the eighth transistor 103 is that the eighth transistor 103 further includes a second oxide layer 133 and a fifth gate electrode layer 122. Further, the difference between the seventh transistor 102 of FIG. 8 and the eighth transistor 103 is that the thickness THK1 of the first gate electrode layer 123 of the eighth transistor 103 is smaller than the thickness THK3 of the first gate electrode layer 123′. The thickness THK1 of the first gate electrode layer 123 of the eighth transistor 103 may be equal to or smaller than the thickness THK2 of the second barrier layer 125.

The threshold voltage of the eighth transistor 103 may be lower than that of the first transistor 101 and the seventh transistor 102. For example, the eighth transistor 103 may be an n-type super-low voltage transistor.

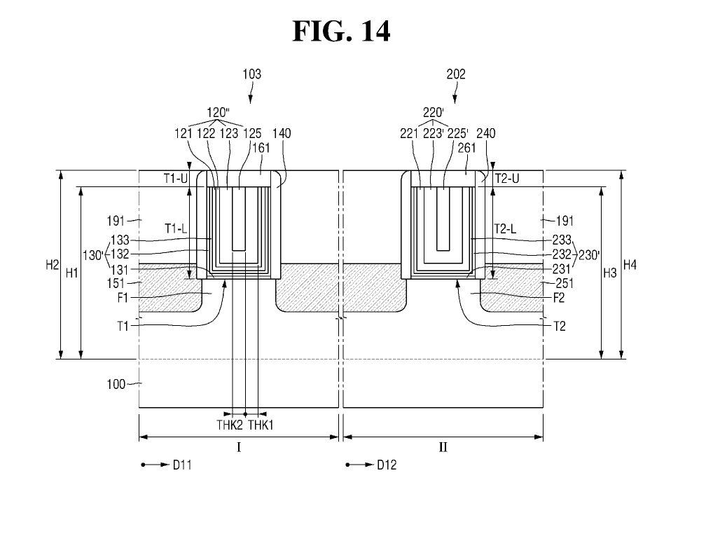

FIG. 14 is a diagram for explaining a semiconductor device according to some embodiments of the present inventive concept. FIG. 14 is a cross-sectional view taken along line A-A′ and line B-B′ of FIG. 1. For the sake of convenience of explanation, differences from those described above will be described.

Referring to FIGS. 1, 4, 13, and 14, a third transistor 202 is formed in the PMOS region II. The third transistor 202 may be the same as the third transistor 202 of FIG. 4. The eighth transistor 103 formed in the NMOS region I may be the same as the eighth transistor 103 of FIG. 13.

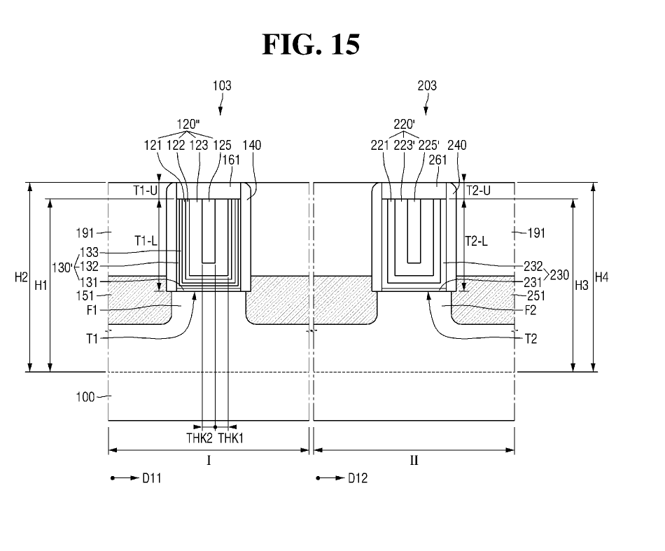

FIG. 15 is a diagram illustrating a semiconductor device according to some embodiments of the present inventive concept. FIG. 15 is a cross-sectional view taken along line A-A′ and line B-B′ of FIG. 1. For the sake of convenience of explanation, differences from those described above will be described.

Referring to FIGS. 1, 5, 13, and 15, a fourth transistor 203 is formed in the PMOS region II. The fourth transistor 203 may be the same as the fourth transistor 203 of FIG. 5. The eighth transistor 103 formed in the NMOS region I may be the same as the eighth transistor 103 of FIG. 13.

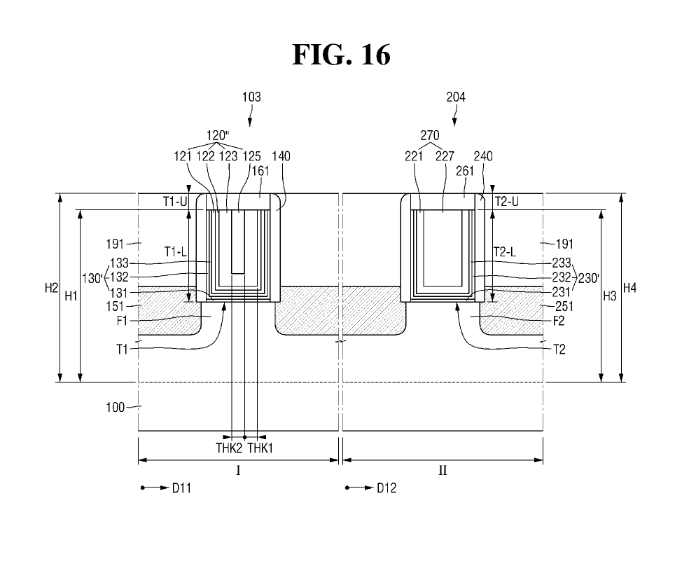

FIG. 16 is a diagram for explaining a semiconductor device according to some embodiments of the present inventive concept. FIG. 16 is a cross-sectional view taken along line A-A′ and line B-B′ of FIG. 1. For the sake of convenience of explanation, differences from those described above will be described.

Referring to FIGS. 1, 6, 13, and 16, a fifth transistor 204 is formed in the PMOS region II. The fifth transistor 204 may be the same as the fifth transistor 204 of FIG. 6. The eighth transistor 103 formed in the NMOS region I may be the same as the eighth transistor 103 of FIG. 13.

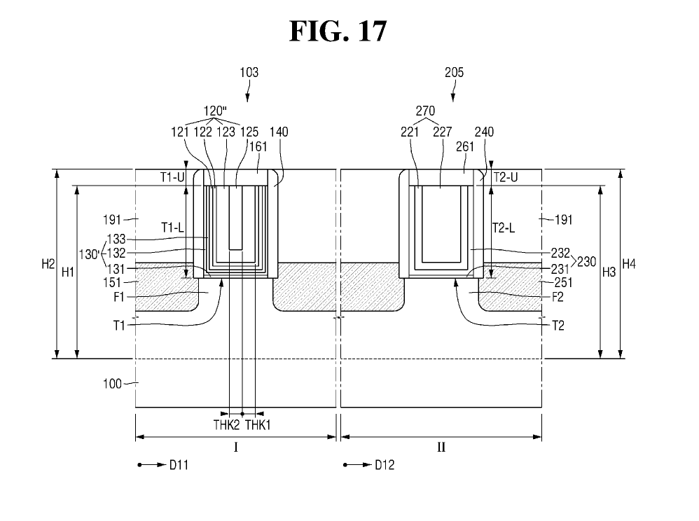

FIG. 17 is a diagram for explaining a semiconductor device according to some embodiments of the present inventive concept. FIG. 17 is a cross-sectional view taken along a line A-A′ and a line B-B′ of FIG. 1. For the sake of convenience of explanation, differences from those described above will be mainly described.

Referring to FIGS. 1, 7, 13, and 17, a sixth transistor 205 is formed in the PMOS region II. The sixth transistor 205 may be the same as the sixth transistor 205 of FIG. 7. The eighth transistor 103 formed in the NMOS region I may be the same as the eighth transistor 103 of FIG. 13.

In the above drawings, the first barrier layer 121 and the third barrier layer 221 are illustrated as a single layer, but the inventive concept is not limited thereto. For example, as described with reference to FIG. 3, at least one of the first barrier layer 121 and the third barrier layer 221 in each drawing may have a multi-layered structure.

Further, in the above drawings, a single transistor is illustrated as being disposed in one region of the substrate 100, but the present inventive concept is not limited thereto. For example, the NMOS region I may be formed in plural in the substrate 100, and any one of the first transistor 101, the seventh transistor 102 and the eighth transistor 103 may be disposed in the NMOS region I in plural. Similarly, the PMOS region II may be formed in plural, and any one of the second transistor 201 to the sixth transistor 205 may be disposed in the PMOS region II in plural.

In an exemplary embodiment, transistors having the same or different threshold voltages may be disposed for each region of the NMOS region I and the PMOS region II. For example, at least two or more of the first transistor 101, the seventh transistor 102 and the eighth transistor 103 are disposed in the NMOS region I, and at least two or more of the second transistor 201 to the sixth transistor 205 may be disposed in the PMOS region II.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A semiconductor device comprising:
a substrate having an NMOS region and a PMOS region;
an interlayer insulating layer disposed on the substrate with a first trench disposed in the NMOS region of the substrate and a second trench disposed in the PMOS region of the substrate;
a first capping layer disposed in an upper portion of the first trench;
a first gate insulating layer disposed in a lower portion of the first trench and extending along sidewalls and a bottom surface of the first trench;
a first gate electrode structure disposed in the lower portion of the first trench and disposed on the first gate insulating layer, wherein the first gate electrode structure includes a first barrier layer disposed on the first gate insulating layer, a first gate electrode layer disposed on the first barrier layer, and a second barrier layer disposed on the first gate electrode layer;
a second capping layer disposed in an upper portion of the second trench;
a second gate insulating layer disposed in a lower portion of the second trench and extending along sidewalls and a bottom surface of the second trench; and
a second gate electrode structure disposed in the lower portion of the second trench and disposed on the second gate insulating layer, wherein the second gate electrode structure includes a third barrier layer disposed on the second gate insulating layer, a second gate electrode layer disposed on the third barrier layer, and a third gate electrode layer disposed on the second gate electrode layer,
wherein the second barrier layer, the first capping layer, the first gate insulating layer, the first barrier layer, and the first gate electrode layer fill the first trench,
wherein the third gate electrode layer, the second capping layer, the second gate insulating layer, the third barrier layer, and the second gate electrode layer fill the second trench,
wherein the first gate electrode layer and the third gate electrode layer include substantially the same material,
wherein the second barrier layer and the second gate electrode layer include substantially the same material, and
wherein the second gate electrode layer and the third gate electrode layer include different materials.

2. The semiconductor device of claim 1,
wherein each of the first gate electrode layer and the third gate electrode layer contains titanium aluminum carbide (TiAlC), and
wherein the second gate electrode layer contains titanium nitride (TiN).

3. The semiconductor device of claim 1,
wherein the first barrier layer is in contact with the first gate insulating layer,
wherein the third barrier layer is in contact with the second gate insulating layer, and
wherein each of the first barrier layer and the third barrier layer contains titanium nitride (TiN).

4. The semiconductor device of claim 1,
wherein a thickness of the first gate electrode layer is greater than a thickness of the second barrier layer.

5. The semiconductor device of claim 1,
wherein a thickness of the first gate electrode layer is equal to the thickness of the second barrier layer or smaller than the thickness of the second barrier layer.

6. The semiconductor device of claim 1, further comprising:
a fifth gate electrode layer interposed between the first barrier layer and the first gate electrode layer,
wherein the fifth gate electrode layer and the second gate electrode layer contain substantially the same material.

7. The semiconductor device of claim 6,
wherein a thickness of the second gate electrode layer is greater than a thickness of the fifth gate electrode layer.

8. The semiconductor device of claim 6, further comprising:
an oxide layer interposed between the first gate insulating layer and the first barrier layer.

9. A semiconductor device comprising:
a substrate having an NMOS region and a PMOS region;
an interlayer insulating layer disposed on the substrate with a first trench disposed in the NMOS region of the substrate and a second trench disposed in the PMOS region of the substrate;
a first capping layer disposed in an upper portion of the first trench;
a first gate insulating layer disposed in a lower portion of the first trench and extending along sidewalls and a bottom surface of the first trench;
a first gate electrode structure disposed in the lower portion of the first trench and on the first gate insulating layer, wherein the first gate electrode structure includes a first barrier layer disposed on the first gate insulating layer, a first gate electrode layer disposed on the first barrier layer, and a second barrier layer disposed on the first gate electrode layer;
a second capping layer disposed in an upper portion of the second trench;
a second gate insulating layer disposed on a lower portion of the second trench and extending along sidewalls and a bottom surface of the second trench; and
a second gate electrode structure disposed in the lower portion of the second trench and on the second gate insulating layer, wherein the second gate electrode structure includes a third barrier layer disposed on the second gate insulating layer, and a fourth gate electrode layer disposed on the third barrier layer,
wherein the second barrier layer, the first gate insulating layer, the first barrier layer, and the first gate electrode layer fill the first trench,
wherein the fourth gate electrode layer, the second gate insulating layer, and the third barrier layer fill the second trench,
wherein the fourth gate electrode layer contains a nitride, and
wherein the first gate electrode layer and the fourth gate electrode layer contain different materials.

10. The semiconductor device of claim 9,
wherein the first gate electrode layer contains titanium aluminum carbide (TiAlC), and
wherein the fourth gate electrode layer contains titanium nitride (TiN).

11. The semiconductor device of claim 9,
wherein the first barrier layer is in contact with the first gate insulating layer,
wherein the third barrier layer is in contact with the second gate insulating layer, and
wherein each of the first barrier layer and the third barrier layer contains titanium nitride (TiN).

12. The semiconductor device of claim 9,
wherein the first barrier layer further comprises a first layer in contact with the first gate insulating layer and a second layer between the first layer and the first gate electrode layer, and
wherein the third barrier layer further comprises a third layer in contact with the second gate insulating layer, and a fourth layer interposed between the third layer and the fourth gate electrode layer.

13. The semiconductor device of claim 9, further comprising:
a fifth gate electrode layer interposed between the first barrier layer and the first gate electrode layer, and
the fourth gate electrode layer and the fifth gate electrode layer contain the same material.

14. The semiconductor device of claim 9,
wherein a thickness of the first gate electrode layer is greater than a thickness of the second barrier layer.

15. The semiconductor device of claim 9,
wherein a thickness of the first gate electrode layer is equal to the thickness of the second barrier layer or smaller than the thickness of the second barrier layer.

16. A semiconductor device comprising:
a substrate having an NMOS region and a PMOS region;
a first gate electrode structure disposed on the NMOS region of the substrate, wherein the first gate electrode structure includes a first barrier layer, a first gate electrode layer and a second barrier layer stacked as listed;
a second gate electrode structure disposed on the PMOS region, wherein the second gate electrode structure includes a third barrier layer, a second gate electrode layer and a third gate electrode layer stacked as listed,
wherein the first gate electrode layer and the third gate electrode layer include substantially the same material, and
wherein the second barrier layer and the second gate electrode layer include substantially the same material.

17. The semiconductor device of claim 16,
wherein the second gate electrode layer and the third gate electrode layer include different materials.

18. The semiconductor device of claim 16, further comprising:
a first gate insulating layer disposed between the NMOS region of the substrate and the first barrier layer,
wherein the first gate insulating layer includes a second oxide and a first high-dielectric constant insulating layer disposed between the second oxide and the NMOS region of the substrate, and
wherein the second oxide includes LaO.

19. The semiconductor device of claim 16, further comprising:
a second gate insulating layer disposed between the PMOS region of the substrate and the third barrier layer,
wherein the second gate insulating layer includes a first oxide and a second high-dielectric constant insulating layer disposed between the first oxide and the PMOS region of the substrate, and
wherein the first oxide includes LaO.

20. The semiconductor device of claim 16, further comprising:
a first fin-type pattern protruding from the NMOS region of the substrate,
wherein the first gate electrode structure is disposed on the first fin-type pattern so that the first fin-type pattern is disposed between the first gate electrode structure and the NMOS region of the substrate; and
a second fin-type pattern protruding from the PMOS region of the substrate,
wherein the second gate electrode structure is disposed on the second fin-type pattern so that the second fin-type pattern is disposed between the second gate electrode structure and the PMOS region of the substrate.
